(19) United States
(12) Patent Application Publication
(10) Pub. No.: US 2008/0191263 A1
(43) Pub. Date: Aug. 14, 2008

(54) Nonvolatile memory devices and methods of fabricating the same

(75) Inventors: Won-joo Kim, Hwaseong-si (KR); June-mo Koo, Seoul (KR); Suk-pil Kim, Yongin-si (KR); Yoon-dong Park, Yongin-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD.

(21) Appl. No.: 11/980,419

(22) Filed: Oct. 31, 2007

(30) Foreign Application Priority Data
Feb. 14, 2007 (KR) 10-2007-0015525

(51) Int. Cl. H01L 29/788; H01L 21/336

(52) U.S. Cl. 257/319; 438/266; 257/E21.409; 257/E29.3

(57) ABSTRACT

Provided are a nonvolatile memory device and a method of fabricating the same in which a channel length is effectively increased and high-integration may be possible. In the nonvolatile memory device, a semiconductor device may include an active region defined by a device isolation film. The active region may include at least one projecting portion. A pair of control gate electrodes may cover both side surfaces of the at least one projecting portion, and may be spaced apart from each other. A pair of charge storage layers may be between both side surfaces of the at least one projecting portion and the pair of control gate electrodes.

### PRIORITY STATEMENT

This application claims priority under 35 U.S.C. § 119 to Korean Patent Application No. 10-2007-0015525, filed on Feb. 14, 2007, in the Korean Intellectual Property Office (KIPO), the entire contents of which are incorporated herein by reference.

### BACKGROUND

1. Field

Example embodiments relate to a semiconductor device and method of fabricating the same. Other example embodiments relate to a nonvolatile memory device that stores data using charge storage layers, and a method of fabricating the nonvolatile memory device.

2. Description of the Related Art

As a degree of integration of nonvolatile memory devices, e.g., flash memory devices, has increased, the channel length of nonvolatile memory devices has decreased causing a short-channel effect. For example, an off-current of the flash memory device may be increased by punch-through, and a threshold voltage of flash memory device may be decreased.

In order to suppress such short-channel effect, increasing an impurity concentration in a body of the flash memory device may be used. However, this increase in impurity concentration may cause a junction leakage current to increase, so that the junction leakage current may prevent or reduce a boosting of a channel voltage. Accordingly, a programming efficiency of the flash memory device may be decreased.

If a multi-level cell (MLC) operation scheme is applied in order to increase data capacity of the flash memory device, the short-channel effect may further affect the flash memory device. As the channel length is decreased, the area of the charge storage layer may also decrease, so that the number of charges, which are capable of being stored in one cell, may be reduced. Accordingly, controlling the number of charges stored in one cell may be difficult, so that control of the MLC operation scheme may become difficult.

### SUMMARY

Example embodiments provide a nonvolatile memory device in which a channel length may be effectively increased and increased integration may be possible. Example embodiments also provide a method of fabricating the nonvolatile memory at decreased costs.

According to example embodiments, a nonvolatile memory device may include a semiconductor substrate including an active region defined by a device isolation film, the active region including at least one projecting portion, a pair of control gate electrodes covering both side surfaces of the at least one projecting portion, and spaced apart from each other, and a pair of charge storage layers between both side surfaces of the at least one projecting portion and the pair of control gate electrodes.

In the nonvolatile memory device, the pair of control gate electrodes may be spaced apart from each other by an upper surface of the at least one projecting portion, and the pair of control gate electrodes may extend toward an upper surface of the at least one projecting portion from both side surfaces of the at least one projecting portion. The nonvolatile memory device may further include a source region and a drain region defined in an upper surface of the at least one projecting portion and the active region on both sides of the at least one projecting portion.

In the nonvolatile memory device, the at least one projecting portion may further include a plurality of projecting portions which are arranged horizontally. Further, the nonvolatile memory device may further include a plurality of control gate electrodes covering both side surfaces of the plurality of projecting portions and spaced apart from each other, and a plurality of charge storage layers between both side surfaces of the plurality of projecting portions and the plurality of control gate electrodes.

According to example embodiments, a method of fabricating a nonvolatile memory device may include forming at least one projecting portion in an active region defined by a device isolation film, forming a pair of charge storage layers covering both side surfaces of the at least one projecting portion, and forming a pair of control gate electrodes on the pair of charge storage layers, the pair of control gate electrodes covering both side surfaces of the at least one projecting portion and spaced apart from each other.

The method may further include defining a source region and a drain region in an upper surface of the at least one projecting portion and the active region on both sides of the at least one projecting portion. The source region and the drain region may be formed by injecting impurity ions into the active region and the upper surface of the at least one projecting portion that is exposed between the pair of control gate electrodes.

### BRIEF DESCRIPTION OF THE DRAWINGS

Example embodiments will be more clearly understood from the following detailed description taken in conjunction with the accompanying drawings. FIGS. 1-8 represent non-limiting, example embodiments as described herein.

FIG. 1 is a perspective view of a nonvolatile memory device according to example embodiments;

FIG. 2 is a graph illustrating current-voltage characteristics of the nonvolatile memory device of FIG. 1, according to example embodiments; and

FIG. 3-FIG. 8 are perspective views of a method of fabricating the nonvolatile memory device of FIG. 1, according to example embodiments, respectively.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. In particular, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will now be described more fully hereinafter with reference to the accompanying drawings, in which example embodiments are shown. Example embodiments may, however, be embodied in many different forms and should not be construed as being limited to the embodiments set forth herein. Rather, these embodiments are provided so that this disclosure will be thorough and complete, and will fully convey the scope of example embodiments to one skilled in the art. In the drawings, the thicknesses of layers and regions are exaggerated for clarity. Like numbers refer to like elements.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

A nonvolatile memory device according to example embodiments may include an Electrically Erasable Programmable Read-Only Memory (EEPROM) device or a flash memory device, for example, however, the scope of example embodiments may not be limited to these types of devices.

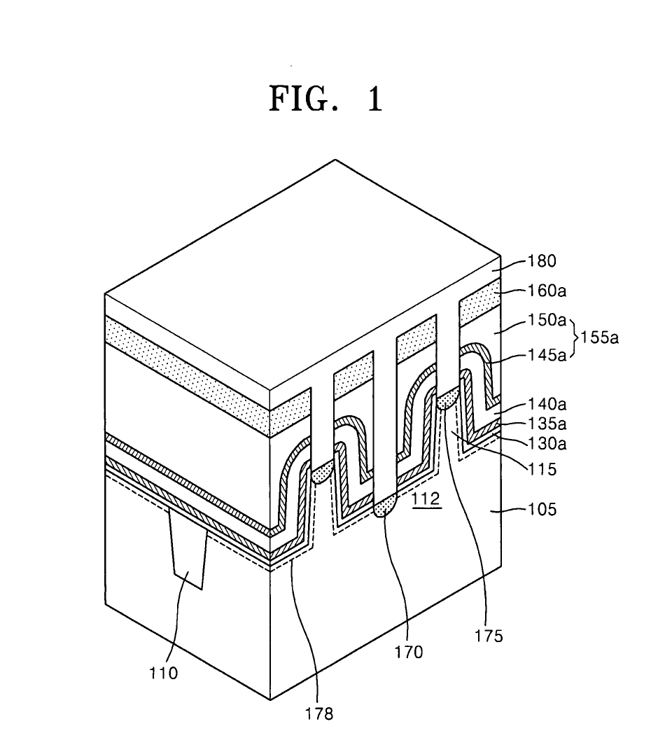

FIG. 1 is a perspective view illustrating the nonvolatile memory device according to example embodiments. Referring to FIG. 1, a semiconductor substrate 105 may include an active region 112, which is defined by a device isolation film 110. For example, the semiconductor substrate 105 may include a bulk semiconductor wafer, e.g., a wafer of silicon, germanium and/or silicon-germanium. In another example, the semiconductor substrate 105 may further include a semiconductor epitaxial layer on the bulk semiconductor wafer.

The device isolation film 110 may extend from the surface of the semiconductor substrate 105 to a predetermined or given depth. For example, the device isolation film 110 may include a suitable insulating layer, e.g., an oxide film and/or a nitride film. The active region 112 of the semiconductor substrate 105 may be defined by the device isolation film 110, so that the active region 112 may be provided in one region or may be separated in several regions according to a shape of the device isolation film 110. Each of the active regions 112 that are separated in several regions may be used as a part of bit lines.

The active region 112 may include one or more projecting portions 115, which project from the semiconductor substrate 105. For example, the projecting portions 115 may be arranged in a line along the active region 112. When the active regions 112 are defined in a plurality of lines, the projecting portions 115, which are in different lines, may be spaced apart by the device isolation film 110. The projecting portions 115 may be arranged in a matrix array. However, the number of projecting portions 115 may be suitably selected and may not limit the scope of example embodiments.

A plurality of control gate electrodes 155a may be arranged to cover both side surfaces of the projecting portions 115. For example, a pair of control gate electrodes 155a may be arranged on both side surfaces of one projecting portion 115, respectively. The control gate electrodes 155a may be spaced apart from each other. For example, the control gate electrodes 155a may be spaced apart from each other in terms of an upper surface of the projecting portions 115 and the active region 112 on both sides of the projecting portions 115.

The control gate electrodes 155a may be arranged as spacers on both sidewalls of the projecting portions 115. For example, the control gate electrodes 155a may be arranged on both sidewalls of the projecting portions 115 so as to have an “L” shape. The control gate electrodes 155a may extend from both sides of the projecting portions 115 onto a top surface of the projecting portions 115. In addition, the control gate electrodes 155a may be arranged in line form so as to further extend across the device isolation film 110.

An arrangement of the control gate electrodes 155a may contribute to improving the degree of integration of the nonvolatile memory device due to the fact that the control gate electrodes 155a are arranged in a three-dimensional form according to both side surfaces of the projecting portions 115. An area of the control gate electrodes 155a in the horizontal plane may be reduced. The nonvolatile memory device of example embodiments may have about twice the degree of integration as compared to a conventional planar structure.

For example, each of the control gate electrodes 155a may include a first conductive layer 145a and a second conductive layer 150a. For example, the first conductive layer 145a may include a metal nitride layer, and the second conductive layer 150a may include a polysilicon layer and/or a metal layer. A plurality of charge storage layers 135a may be interposed between both side surfaces of the projecting portions 115 and the control gate electrodes 155a, respectively. For example, a pair of charge storage layers 135a may be disposed so as to cover both side surfaces of one projecting portion 115. The charge storage layers 135a may include a polysilicon, a silicon nitride film, a quantum dot and/or a nanocrystal. The quantum dot and/or nanocrystal may include a fine crystal of metal and/or semiconductor material.

A plurality of tunneling insulating layers 130a may be further interposed between both side surfaces of the projecting portions 115 and the charge storage layers 135a, respectively. The tunneling insulating layers 130a may have an appropriate thickness for allowing the tunneling of the charge. A plurality of blocking insulating layers 140a may be further interposed between the charge storage layers 135a and the control gate electrodes 155a, respectively. The blocking insulating layers 140a may have an appropriate thickness so as to prevent or retard a reverse tunneling of the charge. For example, the tunneling insulating layers 130a and the blocking insulating layers 140a may include an oxide film, a nitride film and/or a high-k film. The high-k film may be defined by an insulating layer having a greater dielectric constant than those of the oxide film and the nitride film.

A plurality of word line electrodes 160a may be further disposed on the control gate electrodes 155a. Because the control gate electrodes 155a and the word line electrodes 160a have a substantially similar arrangement within the cell region, it should be noted that they are distinguished for the convenience. Accordingly, the control gate electrodes 155a and the word line electrodes 160a may be reversibly used with respect to each other. An interlayer insulating layer 180 may be further disposed on the semiconductor substrate 105 so as to embed between at least one of the control gate electrodes 155a and/or the word line electrodes 160a.

A source region 175 may be defined in an upper surface of the projecting portions 115, and a drain region 170 may be defined in the active region 112 on both side surfaces of the projecting portions 115 in a predetermined or given depth. For example, the source region 175 may be defined in an upper surface of the projecting portions 115 between the control gate electrodes 155a, and the drain region 170 may be defined in the active region 112 between the control gate electrodes 155a.

A portion of the source region 175 and the drain region 170 may extend below the control gate electrodes 155a. Accordingly, in example embodiments, even if the source region 175 and the drain region 170 are defined between the control gate electrodes 155a, the entire region may not be defined between the control gate electrodes 155a in its entirety. The source region 175 and the drain region 170 may be reversibly referred to or may be referred to with the same reference numeral.

Channel regions 178 may be defined in a vicinity of the surface of the active region 112 between the source region 175 and the drain region 170. Accordingly, a relatively large portion of the channel regions 178 may extend along the side surfaces of the projecting portions 115. For example, the length of the channel regions 178 may be further increased by increasing the height of the projecting portions 115. Accordingly, a short channel effect may be suppressed and the degree of integration of the nonvolatile memory device may be enhanced by extending the channel regions 178 vertically with respect to the semiconductor substrate 105.

In addition, as the short-channel effect is suppressed, increasing the impurity concentration in the active region 112 in order to reduce a junction leakage current may not be necessary. Accordingly, the channel boosting voltage may be effectively applied. The nonvolatile memory device according to example embodiments may have an increased programming operational efficiency. As the length of the channel regions 178 increases, the area of the charge storage layers 135a may also increase. Accordingly, the number of charges, which are stored in the charge storage layers 135a, may be increased as compared to the conventional art. Accordingly, the nonvolatile memory device of example embodiments may be useful in a multi-bit operation using a MLC operation.

In example embodiments, the nonvolatile memory device may be constructed as a NAND-type of memory device. One NAND string may be composed of the active region 112, which includes the projecting portion 115 arranged in a line. Accordingly, the current in the bit line may flow through the drain region 170, the channel region 178 and the source region 175. A plurality of NAND strings may be isolated by the device isolation film 110.

However, in example embodiments, the source region 175 and the drain region 170 may be omitted. The channel regions 178 may be connected to each other due to a fringing field by the control gate electrodes 155a. In example embodiments, the nonvolatile memory device may be modified so as to be composed of a NOR-type memory device as would be obvious to one skilled in the art.

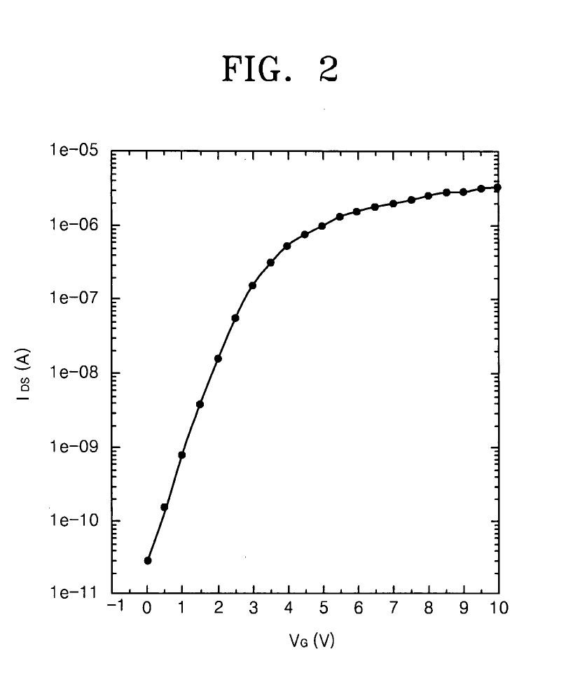

FIG. 2 is a graph illustrating current-voltage characteristics of the nonvolatile memory device of FIG. 1, according to example embodiments. Referring to FIG. 1 and FIG. 2, a voltage V_{G} may be applied to one of the control gate electrodes 155a, and a pass voltage of about 6V may be applied to other control gate electrodes 155a. A current IDS may be measured by applying a relatively high operational voltage of about 1.5V to a bit line, e.g., between the source region 175 and the drain region 170. The increased operational voltage may be relatively high as compared to a conventional decreased operational voltage of about 0.7V.

When the voltage V_{G} is about 0 V, the current IDS in an off state may be relatively low even if the operational voltage is relatively high, e.g., at about 1.5V. Accordingly, a punch-through effect may not occur, even if a relatively high operational voltage of about 1.5V is applied. The channel regions 178 may not be affected by the adjacent control gate electrodes 155a to which the pass voltage is applied. The current IDS, which is in the off state, may be generated because the length of the channel region 178 became longer than that of the conventional technique. In addition, because a relatively high operational voltage of about 1.5V is applied to a bit line, a current IDS in an on-state may be about 2-3×10⁻⁶ A, which is relatively high.

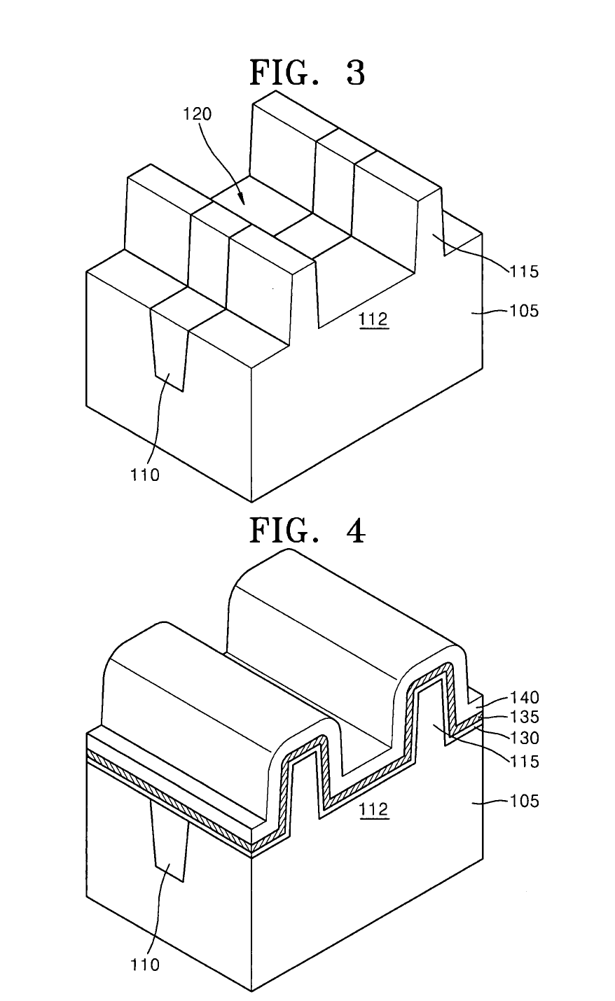

FIG. 3-FIG. 8 are perspective views of a method of fabricating the nonvolatile memory device of FIG. 1, according to example embodiments. Referring to FIG. 3, the active region 112 may be defined by forming the device isolation film 110 in the semiconductor substrate 105. For example, the device isolation film 110 may be formed by forming a trench (not shown) in the semiconductor substrate 105, and then, embedding the trench with an insulating layer. The device isolation film 110 may be further planarized so that the device isolation film 110 may be flush with the surface of the active region 112. For example, the planarization of the device isolation film 110 may be performed using an etch-back and/or a chemical mechanical polishing (CMP) method.

Subsequently, a trench 120 may be formed across the active region 112 and the device isolation film 110. Accordingly, the projecting portions 115, which are extended over the semiconductor substrate 105, may be defined in the active region 112. In example embodiments, the trench 120 may first be formed, and then, the device isolation film 110 may be formed.

Referring to FIG. 4, a tunnel insulating layer 130, a charge storage layer 135 and a blocking insulating layer 140 may be sequentially formed on the semiconductor substrate 105 so as to cover the projecting portions 115. For example, the tunnel insulating layer 130 may be selectively formed on the active region 112 using a thermal oxidation method, or may be formed as one layer on the active region 112 and the device isolation film 110 using a CVD method.

The charge storage layer 135 may be formed on the tunnel insulating layer 130, and the blocking insulating layer 140 may be formed on the charge storage layer 135. For example, the charge storage layer 135 and the blocking insulating layer 140 may be formed using the CVD method.

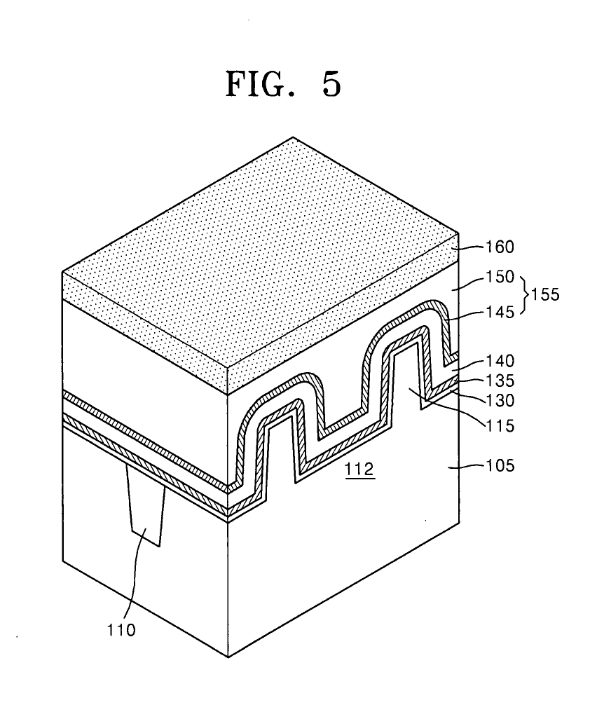

Referring to FIG. 5, a control gate electrode layer 155 may be formed on the blocking insulating layer 140. A word line electrode layer 160 may be further formed on the control gate electrode layer 155. For example, the control gate electrode layer 155 may include a first conductive layer 145 and a second conductive layer 150. The first conductive layer 145 may have a predetermined or given etching selection ratio comparable to the second conductive layer 150. For example, the first conductive layer 145 may include a metal nitride film, and the second conductive layer 150 may include polysilicon and/or metal. The word line electrode layer 160 may include metal and/or metal silicide.

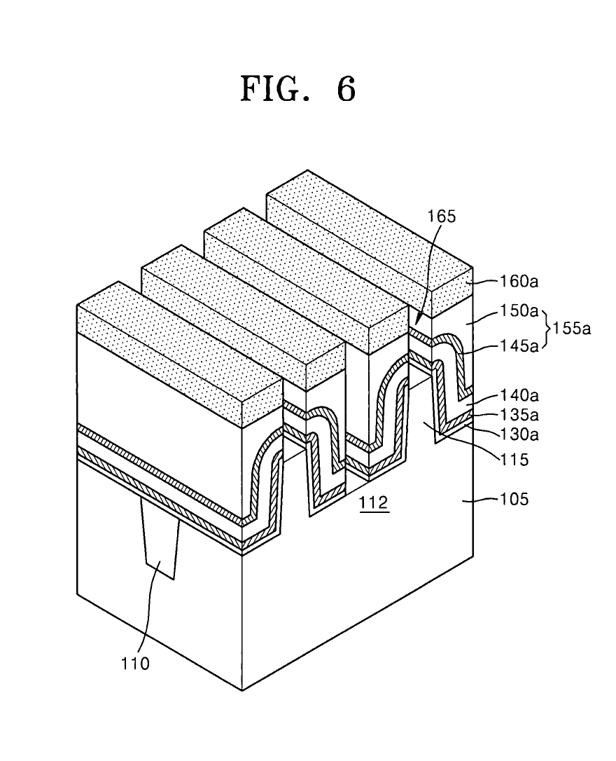

Referring to FIG. 6, the word line electrodes 160a, the control gate electrodes 155a, the blocking insulating layers 140a, the charge storage layers 135a and the tunneling insulating layers 130a may be separately formed by forming trenches 165. The control gate electrodes 155a may include the first conductive layers 145a and the second conductive layers 150a that are separate from each other due to the trenches therebetween.

For example, the trenches 165 may be formed by etching and separating the word line electrode layer 160, second conductive layer 150, the control gate electrode layer 155, the blocking insulating layer 140, the charge storage layer 135, and the tunneling insulating layer 130 so as to expose a portion of an upper surface of the projecting portions 115 and a portion of the active region 112 on both sides of the projecting portions 115. By forming the trenches 165, the first conductive layers 145a may serve as an etch stopper film. The trenches 165 may be self-aligned by the first conductive layers 145a.

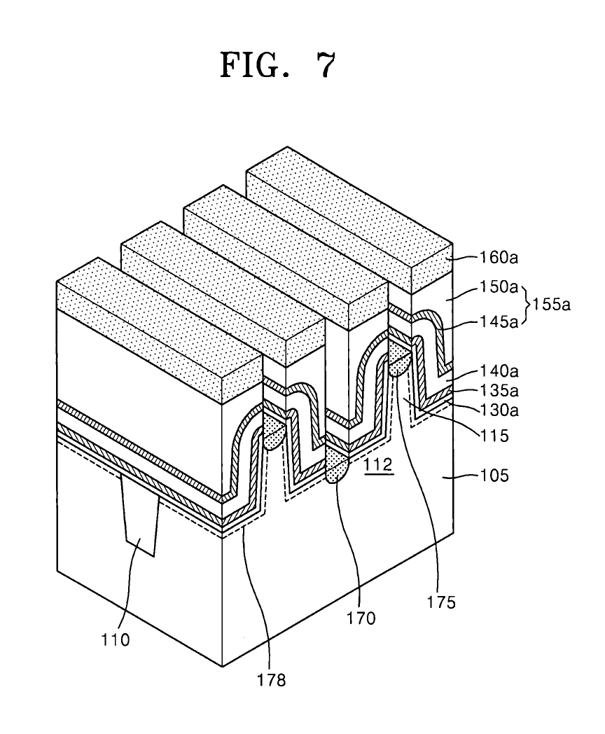

Referring to FIG. 7, the source region 175 and the drain region 170 may be formed by injecting impurity ions into the active region 112 and the projection portions 115 exposed from the trenches 165. For example, the source region 175 may be defined in a portion of the upper surface of the projecting portions 115, and the drain region 170 may be defined in a portion of the active region 112 on both sides of the projecting portions 115. For example, if the semiconductor substrate 105 is doped by a first conductive type of impurity, the source region 175 and the drain region 170 may be doped by a second conductive type of impurity opposite to the first conductive type of impurity of the semiconductor substrate 105.

The first conductive type and a second conductive type of impurity may be n-type and/or p-type. The impurities injected into the source region 175 and the drain region 170 may then be activated and diffused by a thermal process. Therefore, the source region 175 and the drain region 170 may be further extended to the active region 112 under the control gate electrodes 155a. The channel regions 178 may be defined the surface of the active region 112 between the source region 175 and the drain region 170. However, in example embodiments, the source region 175 and the drain region 170 may be omitted, and thus, the channel regions 178 may further be extended and connected to each other.

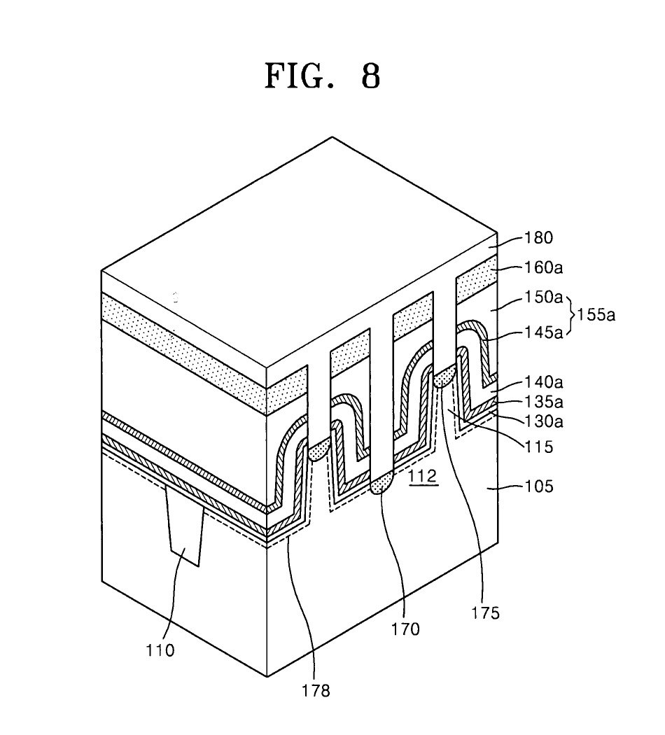

Referring to FIG. 8, the interlayer insulating layer 180 may be formed on the semiconductor substrate 105 so as to embed between at least one of the control gate electrodes 155a and the word line electrodes 160a. For example, the interlayer insulating layer 180 may be formed using a CVD method and may be planarized by the CVD method. Subsequently, the nonvolatile memory device may be completed according to a method that is well known to one skilled person in the art.

According to the nonvolatile memory device of example embodiments, the channel region may be lengthily formed along the projecting portion, so that the short-channel effect may be suppressed and high-integration may be achieved. Accordingly, the junction leakage current and the off current may be lowered and the channel boosting voltage may be effectively applied to the nonvolatile memory device. As a result, an operating reliability of the nonvolatile memory device may be improved.

In addition, according to the nonvolatile memory device of example embodiments, the area of the charge storage layer may be enlarged so that the number of charges stored in the charge storage layer increases. Accordingly, the nonvolatile memory device according to example embodiments may be useful in an MLC operation, so that the nonvolatile memory device may be useful in a multi-bit operation.

The above descriptions on the particular example embodiments are given for the purpose of illustration and description. It is apparent that example embodiments are not limited to the embodiment as described above, and various modifications and variations are possible by embodying the embodiments in combination by a one skilled in the art without departing from the technical spirit of example embodiments.

What is claimed is:

1. A nonvolatile memory device, comprising:
a semiconductor substrate including an active region defined by a device isolation film, the active region including at least one projecting portion;
a pair of control gate electrodes covering both side surfaces of the at least one projecting portion, and spaced apart from each other; and
a pair of charge storage layers between both side surfaces of the at least one projecting portion and the pair of control gate electrodes.

2. The nonvolatile memory device of claim 1, wherein the pair of control gate electrodes are spaced apart from each other by an upper surface of the at least one projecting portion.

3. The nonvolatile memory device of claim 1, wherein the pair of control gate electrodes extends toward an upper surface of the at least one projecting portion from both side surfaces of the at least one projecting portion.

4. The nonvolatile memory device of claim 1, further comprising:
a source region and a drain region defined in an upper surface of the at least one projecting portion and the active region on both sides of the at least one projecting portion.

5. The nonvolatile memory device of claim 4, wherein the source region is defined in the upper surface of the at least one projecting portion which is exposed between the pair of control gate electrodes, and the drain region is defined in the active region which is exposed between the pair of control gate electrodes.

6. The nonvolatile memory device of claim 1, further comprising:
a pair of tunneling insulating layers between both side surfaces of the at least one projecting portion and the pair of charge storage layers; and
a pair of blocking insulating layers between the pair of charge storage layers and the pair of control gate electrodes.

7. The nonvolatile memory device of claim 1, wherein the pair of control gate electrodes extends across the device isolation film.

8. The nonvolatile memory device of claim 1, further comprising:
an interlayer insulating layer on the semiconductor substrate so as to embed between the pair of control gate electrodes.

9. The nonvolatile memory device of claim 1, wherein the at least one projecting portion further includes a plurality of projecting portions arranged horizontally.

10. The nonvolatile memory device of claim 9, further comprising:
a plurality of control gate electrodes covering both side surfaces of the plurality of projecting portions, and spaced apart from each other; and
a plurality of charge storage layers between both side surfaces of the plurality of projecting portions and the plurality of control gate electrodes.

11. The nonvolatile memory device of claim 10, wherein the plurality of control gate electrodes are spaced apart from each other by the upper surface of the plurality of projecting portions and the active region on both sides of the plurality of projecting portions.

12. The nonvolatile memory device of claim 11, further comprising:
a source region and a drain region defined in the upper surface of the plurality of projecting portions between the plurality of control gate electrodes and the active region on both sides of the plurality of projecting portions.

13. The nonvolatile memory device of claim 10, further comprising:
a plurality of tunneling insulating layers between both side surfaces of the plurality of projecting portions and the plurality of charge storage layers; and
a plurality of blocking insulating layers between the plurality of charge storage layers and the plurality of control gate electrodes.

14. The nonvolatile memory device of claim 10, wherein the plurality of control gate electrodes extend across the device isolation film.

15. The nonvolatile memory device of claim 10, further comprising:
a plurality of word line electrodes arranged on the plurality of control gate electrodes so as to extend across the device isolation film.

16. A method of fabricating a nonvolatile memory device, comprising:
forming at least one projecting portion in an active region defined by a device isolation film;
forming a pair of charge storage layers covering both side surfaces of the at least one projecting portion; and
forming a pair of control gate electrodes on the pair of charge storage layers, the pair of control gate electrodes covering both side surfaces of the at least one projecting portion and spaced apart from each other.

17. The method of claim 16, wherein the pair of control gate electrodes are spaced apart from each other by the upper surface of the at least one projecting portion and the active region on both sides of the at least one projecting portion.

18. The method of claim 16, wherein forming the at least one projecting portion includes forming a plurality of trenches across the device isolation film in the active region.

19. The method of claim 16, wherein forming the pair of charge storage layers and forming the pair of control gate electrodes includes:
forming a charge storage layer on the active region so as to cover the at least one projecting portion;
forming a control gate electrode layer on the charge storage layer; and
separating the charge storage layer and the control gate electrode layer into the charge storage layers and the control gate electrode layers over the projecting portions and the active region.

20. The method of claim 16, further comprising:
defining a source region and a drain region in an upper surface of the at least one projecting portion and the active region on both sides of the at least one projecting portion.

21. The method of claim 20, wherein the source region and the drain region are formed by injecting impurity ions into the active region and the upper surface of the at least one projecting portion that are exposed between the pair of control gate electrodes.

22. The method of claim 16, further comprising:
forming a plurality of tunneling insulating layers between both side surfaces of the at least one projecting portion and the pair of charge storage layers; and
forming a plurality of blocking insulating layers between the pair of charge storage layers and the pair of control gate electrodes.

23. The method of claim 16, wherein the pair of control gate electrodes extend across the device isolation film.

24. The method of claim 16, further comprising:
forming a plurality of word line electrodes on the pair of control gate electrodes so as to extend across the device isolation film.

25. The method of claim 16, further comprising:
forming an interlayer insulating layer on the semiconductor substrate so as to embed between the pair of control gate electrodes.

26. The method of claim 16, wherein the at least one projecting portion further includes a plurality of projecting portions arranged horizontally.
